(19) United States
(12) Patent Application Publication
(10) Pub. No.: US 2004/0003837 A1
(43) Pub. Date: Jan. 8, 2004

(54) Photovoltaic-photoelectrochemical device and processes

(75) Inventor: Michael G. Mauk, Newark, DE (US)

Correspondence Address: BURR & BROWN, PO BOX 7068, SYRACUSE, NY, 13261-7068, US

(73) Assignee: AstroPower, Inc., Newark, DE

(21) Appl. No.: 10/421,377

(22) Filed: Apr. 23, 2003

Related U.S. Application Data
(60) Provisional application No. 60/375,575, filed on Apr. 25, 2002.
(60) Provisional application No. 60/375,046, filed on Apr. 24, 2002.

(51) Int. Cl. H01L 31/00

(52) U.S. Cl. 136/244; 136/260; 136/263; 439/111; 438/80

(57) ABSTRACT

There are provided photovoltaic-photoelectrochemical devices each comprising a diode and a plurality of separate photocathode elements. Preferably, the devices are positioned in a container in which they are at least partially immersed in electrolyte. Preferably, the devices are positioned in a container which has at least one photocathode reaction product vent and at least one anode reaction product vent. Preferably, the devices are positioned in a container which has an internal partial wall extending from a top portion of the container toward, but not reaching, a bottom portion of the container, the internal partial wall being positioned between the photocathode elements and an anode element which is electrically connected to the p-region of the diode. There are also provided photovoltaic-photoelectrochemical methods using such devices, and methods of making such devices.

### CROSS-REFERENCE TO RELATED APPLICATIONS

This application claims the benefit of U.S. Provisional Patent Applications Nos. 60/375,046, filed Apr. 24, 2002 and 60/375,575, filed Apr. 25, 2002, the entireties of which are hereby incorporated herein by reference.

### FIELD OF THE INVENTION

The present invention is directed to photovoltaic-photoelectrochemical devices, methods of making such devices, and photovoltaic-photoelectrochemical processes. The present invention is also directed to structures which are useful in manufacturing such devices and structures which are useful in such processes.

In a preferred aspect, the present invention is directed to a photovoltaic-photoelectrochemical process for production of hydrogen by electrolysis of water using solar energy, and to a photovoltaic-photoelectrochemical device for use in such a process.

### BACKGROUND OF THE INVENTION

The present invention relates to photovoltaic-photoelectrochemical processes, photovoltaic-photoelectrochemical devices for use in carrying out photovoltaic-photoelectrochemical processes, and methods for making such devices.

In a photovoltaic-photoelectrochemical process, solar energy is used to provide energy needed for one or more electrolysis reaction. The one or more electrolysis reaction produces one or more compound which can be used to generate energy in a further chemical reaction. For example, an electrolysis reaction can convert a single compound into two or more electrolysis products, one or both of which can then be used in the reverse reaction (i.e., the reverse of the electrolysis reaction) to generate energy. A particularly preferred electrolysis reaction according to the present invention is electrolysis of water to produce hydrogen and oxygen, the hydrogen thus produced being recovered as a fuel (e.g., hydrogen can be reacted with oxygen to form water, a reaction which releases energy).

In an electrolysis reaction, a pair of electrodes are immersed in an electrolyte solution which contains the compound or compounds to be electrolyzed, and power is applied to the electrodes so as to generate a positive charge at one electrode (the anode) and a negative charge at the other electrode (the cathode). At the anode, the negatively-charged component(s) of the compound(s) being electrolyzed releases electrons. Meanwhile, at the cathode, positively-charged component(s) of the compound(s) being electrolyzed absorbs electrons. These half-reactions together result in electrolysis of the compound(s), and release of the electrolysis products (in electrically neutral form) at the respective electrodes. In the case of electrolysis of water, water molecules are in the following equilibrium:

2H₂O⇄4H⁺+2O²⁻,

the anode half-cell reaction is:

2O²⁻→O₂+4e⁻ (i.e., at the anode, oxygen is the negatively-charged component),

the cathode half-cell reaction is:

4H⁺+4e⁻→2H₂ (i.e., at the cathode, hydrogen is the positively-charged component),

and so the overall electrolysis reaction is:

2H₂O→O₂+2H₂.

As is well known, a photovoltaic cell (i.e., a solar cell) comprises a diode comprising a semiconductor substrate having at least one n-type region (i.e., a region of the semiconductor which is doped with an n-type dopant, also referred to herein as an n-region) and at least one p-type region (i.e., a region of the semiconductor which is doped with a p-type dopant, also referred to herein as a p-region), with the interface(s) where the n-type region(s) meets the p-type region(s) being referred to as the p-n junction(s).

Typically, a diode is formed by doping a first region of a semiconductor substrate (e.g., made of silicon, germanium and/or gallium arsenide) with a p-type dopant (e.g., boron, aluminum, gallium or indium) and doping a second region of the semiconductor substrate with an n-type dopant (e.g., phosphorus, arsenic or antimony), the second region abutting the first region.

In a typical solar-electric system, a p-region metal contact layer is electrically connected to the p-type region, an n-region metal contact layer is electrically connected to the n-type region, both of which are connected to a load through an external circuit.

The amount of power a photovoltaic cell generates is proportional to its area; thus, there is a premium on maximizing the area of the photovoltaic device. Therefore, solar cells are typically made in a thin wafer, sheet, or thin-film geometry.

Semiconductors are normally exploited for their electronic and optical properties that enable various devices such as transistors, light-emitting diodes, photodetectors, solar cells, etc.. Perhaps less known, but nevertheless well established, is the use of semiconductors as electrodes in electrolysis reactions. For instance, electrodes can be made out of semiconductor materials such silicon and GaP, much as electrodes are made out platinum or other metals in some very conventional electrolysis or electroplating operations, or in batteries. In some situations, semiconductor electrodes can be more selective for the reactions they induce or catalyze in electrolysis processes. More important with regard to the present invention, is that many semiconductors can absorb high energy (short-wavelength) photons of incident light, the energy of which can be utilized to power the electrolysis reaction. Thus, the amount of energy supplied by an external electric source to power the electrolysis reaction can be considerably reduced, since some of the required power (fixed by the thermodynamics of the electrolysis reaction) is provided by absorbed photons of any light incident on the semiconductor electrode. It might be hoped that the incident light absorbed by the semiconductor electrode could provide all of the energy needed for the electrolysis reaction, and thus the external power source could be dispensed with. However, although very appealing for its simplicity, the combination of the energetics of most electrolysis reactions, the energy absorption characteristics of most semiconductors, and the range of available photon energies available in the spectrum of sunlight, conspire to make the efficiency of such a scheme relatively poor. Instead, one can design a semiconductor cathode system for electrolysis reactions wherein part of the energy is provided by absorbed photons of incident sunlight, and part is provided by an electrical power source. Nevertheless, the power source need not be external to the system. A ‘self-contained’ power source is possible by situating a solar cell in close proximity to the photocathode and electrically connecting one lead of the solar cell to the photocathode, and another lead of the solar cell to a separate anode. This is especially appealing since the photocathode can only absorb and utilize high energy photons. (Sunlight has a wide distribution of photon energies.) Some of the remaining unabsorbed photons can be used by the solar cell to generate the bias voltage and current supplied to the photocathode. An especially compact configuration would stack the photocathode on top of the solar cell. The entire arrangement would be immersed in an electrolyte solution and exposed to sunlight. Incident light would pass through the electrolyte. A fraction of the sunlight (containing the high-energy photons would be absorbed in the semiconductor photocathode as part of the electrolysis reaction; some of the remaining fraction of the sunlight (containing the low-energy photons) would pass through the photocathode (the photocathode is transparent to low-energy photons) and be absorbed in the underlying solar cell, thus energizing it sufficiently and such that with proper electrical connections can provide a current and voltage to the overlain photocathode needed for the electrolysis reaction.

In summary then, photovoltaic-photoelectrochemical cells combine two functions in one device: (1) the device acts as a photocathode, absorbing high energy photons of sunlight and using this absorbed energy to help drive an electrolysis reaction, and (2) the device has a ‘built-in’ solar cell that absorbs low-energy photons and generates a voltage and electric current that provides the additional electrical energy needed at the photocathode to power the electrolysis reaction. In a photovoltaic-photoelectrochemical cell, as mentioned above, energy from a solar cell is used to provide energy needed for one or more electrolysis reaction. One type of photovoltaic-photoelectrochemical device which has been used includes a diode comprising an n-type region and a p-type region, a photocathode layer electrically connected to the n-type region, and an anode electrically connected to the p-type region, in which the diode and the electrodes are all immersed in a slightly acidic aqueous electrolyte solution. The electrolyte solution can be held in a container which preferably has separate vents for collecting the hydrolysis product (hydrogen, in the case of hydrolysis of water) produced at the photocathode and collecting and/or releasing the hydrolysis product (oxygen, in the case of hydrolysis of water) produced at the anode. In order to minimize the area used, the photocathode is preferably positioned over the solar cell. Accordingly, in order to avoid loss of efficiency due to absorption of light by the photocathode, the photocathode is typically formed of a material which is substantially transparent to at least most of the low energy light (i.e., long wavelength light), e.g., infrared light.

To our knowledge, prior photovoltaic-photoelectrochemical devices have in general required the use of comparatively expensive materials for the diode (and/or other components), and/or complicated layering between the photocathode and the n-type region of the diode in order to provide efficient electrolysis while (1) avoiding large defect density (which significantly reduces photovoltaic efficiency), (2) avoiding excessive stress, (3) avoiding cracking and/or peeling of the photocathode (or of one or more layers between the photocathode and the n-type region of the diode), (4) providing substantial transparency to at least low energy light (i.e., long wavelength light) in order to maximize the intensity of low energy light (e.g., infrared light) reaching the diode, and (5) providing electrical contact with the electrolyte solution which allows for efficient production of the electrolysis product(s).

For example, it has been seen that a layer of indium gallium phosphide (InGaP) can be readily grown epitaxially directly on a solar cell having a substrate of gallium arsenide, due to the high degree of similarity between the respective crystal structures of the materials. However, if a typical solar cell having a substrate of silicon is used instead of a solar cell having a substrate of gallium arsenide (e.g., to reduce cost relative to the use of a gallium arsenide substrate), significant lattice defects and stress result from attempting to grow InGaP directly on silicon. Even where GaAs is grown on silicon, and then InGaP is grown on the GaAs, the resulting product is highly prone to cracking and peeling, and has an extremely rough surface morphology.

### BRIEF SUMMARY OF THE INVENTION

In accordance with the present invention, a photovoltaic-photoelectrochemical device is provided which enables a wider variety of options for selecting materials out of which the substrate, the photocathode, and any layers in between the substrate and the photocathode can be selected, and which, for particular substrate-photocathode combinations, eliminates the need for, or reduces the required number of, layers between the substrate and the photocathode (some known devices include as many as 5 or 6 stacked layers in order to reduce or avoid lattice defects). In addition, the present invention provides methods of making a photovoltaic-photoelectrochemical device by simpler processes, as well as methods of making a photovoltaic-photoelectrochemical device in which the process steps used are simpler and less expensive.

Therefore, according to the present invention, photovoltaic-photoelectrochemical devices can be constructed of less expensive materials than conventional photovoltaic-photoelectrochemical cells, and/or can be of simpler construction than conventional photovoltaic-photoelectrochemical cells. The present invention is further directed to methods of making such devices, and to photovoltaic-photoelectrochemical processes. The present invention is also directed to structures which are useful in manufacturing such devices and in such processes.

In order to obtain efficient electrolysis, the material out of which the photocathode is made typically differs from the material out of which the underlying solar cell is made. Such differences tend to create problems when the photocathode material is deposited on the substrate of the diode, as discussed below. Photocathode materials are typically made of materials which are most suitably deposited on the diode epitaxially.

Two factors which commonly limit the specific materials which can be epitaxially deposited a semiconductor substrate are that (1) lattice mismatch between respective materials often creates unacceptably large stress and/or unacceptably high lattice defect density, and (2) difference in thermal contraction of materials (e.g., upon cooling after depositing the material on the semiconductor substrate) often creates unacceptably large stress.

As a result, it is either necessary or desirable to restrict the choice of materials combinations to ones which have close lattice constants and thermal expansion coefficients, or else design complicated multilayer structures that partially ameliorate the effects of lattice mismatch and thermal expansion mismatch, For instance, in order to employ desired materials in a semiconductor device, some workers include one or more intermediate layers having lattice properties and/or thermal contraction properties which are between those of the desired materials in order to create a laminate in which each pair of layers in contact with each other have a less drastic difference in such properties. This approach, and similar ones, has proven less than completely satisfactory.

In accordance with the present invention, there are provided methods and devices in which the options for the materials out of which adjacent layers can be made are broadened. That is, according to the present invention, layers which ordinarily cannot be (or desirably are not) combined with each other in a viable semiconductor device (without causing high stress and/or lattice defect density), can be combined with each other (with comparatively lower stress and/or lower lattice defect density) when utilizing the design features of the present invention.

According to the present invention, there is provided a photovoltaic-photoelectrochemical device comprising a photovoltaic solar cell device integrated with a photocathode, and optionally one or more intermediate layers positioned between the diode and the photocathode, in which the effects of any lattice mismatch and/or any thermal expansion/contraction difference between the photocathode and the layer on which the photocathode is formed are minimized by forming the photocathode as a discontinuous layer, i.e., the photocathode is in the form of a plurality of separate photocathode elements, preferably arranged in a pattern. Due to the unique nature of a photovoltaic-photoelectrochemical device, unlike other semiconductor devices and solar cell devices, the photocathode can be formed as a discontinuous layer. That is, in a photovoltaic-photoelectrochemical device having a fluid electrolyte solution, unlike other semiconductor devices and other solar cell devices, electrical contact can readily be formed with a discontinuous photocathode (i.e., a plurality of separate photocathode elements) without the need to provide any structure which electrically links the separate photocathode elements together, because the photocathode elements are immersed in the electrolyte solution.

Also according to the present invention, where one or more intermediate layers are present, preferably the intermediate layer (or, where there are more than one intermediate layers, each of them, or one or more of them) is also discontinuous, i.e., is in the form of a plurality of separate intermediate elements, the intermediate elements preferably being arranged in a pattern which is similar to or identical to a pattern in which the photocathode elements are arranged. By forming one or more such intermediate layers, if any are present, as a plurality of separate intermediate elements, the effects of any lattice mismatch and/or any thermal contraction difference between any such discontinuous layers and the layer or layers in contact with that discontinuous layer are substantially reduced.

According to the present invention, even where layers in contact with one another are formed of respective materials which have significant differences in lattice properties and/or thermal contraction properties, where one (or each) of the layers is in the form of a discontinuous layer including a plurality of elements, each of the dimensions of each of the plurality of elements being small enough that stress and lattice defect density are reduced compared to what they would be if the respective materials were each in the form of continuous elements, the effects of such differences are minimized. Furthermore, the present invention provides improved morphology compared to where layers are formed as continuous elements.

Thus, the present invention provides a photovoltaic-photoelectrochemical device, comprising:

at least one diode comprising at least one n-type region and at least one p-type region, the n-type region and the p-type region being in contact with each other, thereby forming a p-n junction; and

a plurality of separate photocathode elements, each photocathode element being electrically connected with the n-type region, each photocathode element comprising an electrically conductive material.

Preferably, the photovoltaic-photoelectrochemical device further includes at least one anode element which is electrically connected to the p-type region. Preferably, the at least one anode element is separate from the diode, and is electrically connected to the p-type region through a p-region contact layer provided on the p-type region and an anode line which provides electrical connection between the p-region contact layer and the anode.

Preferably, the photovoltaic-photoelectrochemical device further comprises at least one container comprising at least one bottom portion and at least one sidewall portion. Preferably, the container further has a top portion, a photocathode reaction product vent and an anode reaction product vent. Preferably, the container defines an internal volume which is gas-tight and liquid-tight, with the exception of the photocathode reaction product vent and the anode reaction product vent. Preferably, the container comprises an internal partial wall positioned between (1) the diode and the plurality of photocathode elements and (2) the anode element, but leaving a passageway for liquid communication between the photocathode elements and the anode.

In use, an electrolyte solution is positioned in the container, the electrolyte solution comprising at least one electrolyzable compound, so that at least the photocathode elements and the anode element are at least partially immersed in the electrolyte solution.

In one aspect of the present invention, the diode can comprise a doped polycrystalline material, e.g., doped polysilicon.

The present invention is also directed to a photovoltaic-photoelectrochemical process, comprising subjecting a photovoltaic-photoelectrochemical device as described above to sunlight.

The present invention is further directed to a method of making a photovoltaic-photoelectrochemical device, comprising epitaxially forming a plurality of separate photocathode elements on a diode (i.e., each formed directly on the diode or with optionally one or more intermediate layers or elements positioned between the diode and the photocathode element), the diode comprising at least one semiconductor having at least one n-type region and at least one p-type region, the n-type region and the p-type region forming a p-n junction, each photocathode element being electrically connected with the n-type region.

The invention may be more fully understood with reference to the accompanying drawings and the following description of the embodiments shown in those drawings.

### BRIEF DESCRIPTION OF THE DRAWING FIGURES

FIG. 1 is a schematic side view of an embodiment of a photovoltaic-photoelectrochemical device in accordance with the present invention.

FIG. 2 is a schematic side view of a substrate for use in a first embodiment of a process according to the present invention.

FIG. 3 is a schematic side view of the substrate of FIG. 2, with a film of GaAs deposited thereon according to the first embodiment of a process according to the present invention.

FIG. 4 is a schematic side view of the article of FIG. 3, after the film of GaAs has been patterned into a plurality of GaAs intermediate elements according to the first embodiment of a process according to the present invention.

FIG. 5 is an overhead view of the article of FIG. 4.

FIG. 6 is a schematic side view of the article of FIG. 4, with a photocathode element positioned on each of the intermediate elements.

FIG. 7 is a schematic side view of a substrate for use in a second embodiment of a process according to the present invention.

FIG. 8 is a schematic side view of the substrate of FIG. 7, with a thermally-grown silicon dioxide layer according to the second embodiment of a process according to the present invention.

FIG. 9 is a schematic side view of the article of FIG. 8, after the thermally-grown silicon dioxide layer has been patterned to form openings in the thermally-grown silicon dioxide layer according to the second embodiment of a process according to the present invention.

FIG. 10 is a schematic side view of the article of FIG. 9, after regions of GaAs have been formed in the openings in the silicon dioxide layer according to the second embodiment of a process according to the present invention.

FIG. 11 is an overhead view of the article of FIG. 10.

FIG. 12 is a schematic side view of the article of FIG. 10, with a photocathode element positioned on each of the intermediate elements.

### DETAILED DESCRIPTION OF THE INVENTION

In accordance with the present invention, there is provided a photovoltaic-photoelectrochemical device, comprising at least one photovoltaic diode comprising at least one n-type region and at least one p-type region. The n-type region and the p-type region are in contact with each other, so as to form a p-n junction.

A variety of photovoltaic diodes are known in the art. The invention is applicable to any known photovoltaic diode. In one aspect of the present invention, at least the n-type region of the diode can comprise a doped polycrystalline material, e.g., doped polysilicon. Silicon (either polycrystalline or single crystal) is a particularly desirable material, especially in terms of cost, for use in making the substrate of the photovoltaic diode. In general, however, any other material which can be used in making a photovoltaic diode can be used according to the present invention, e.g., GaAs and Ge (currently, GaAs and Ge substrates are considerably more expensive than Si substrates).

Any dopant which is suitable for making an n-type region can be used according to the present invention, and any dopant which is suitable for making a p-region can be used according to the present invention.

Preferably, the overall shape of the substrate is generally prismatic, having a width, a depth, and a thickness, the thickness being smaller, preferably substantially smaller, than the width or the depth.

The n-type region and p-region can generally be of any suitable shape. The n-type region and p-region preferably each have at least one surface along an outer surface of the substrate (i.e., neither the n-region nor the p-region is completely surrounded with undoped substrate material or oppositely-doped substrate material) as well as at least one p-n junction (i.e., at least one boundary of the n-region, preferably a major, substantially flat boundary, abuts at least one boundary of the p-region, likewise preferably a major, substantially flat boundary). Other device configurations, such as wherein the position of the p- and n-type region are reversed are also possible.

As noted above, at least one photocathode layer is provided which comprises a plurality of photocathode elements which are separate, i.e., non-integral with one another. Preferably, the photocathode elements of a photocathode layer are coplanar, but the photocathode elements of a photocathode layer can instead be non-coplanar (for example, the photocathode layer can be deposited on a substrate surface, or on surfaces of intermediate members, which are not coplanar and/or which are not flat). Each of the photocathode elements are electrically conductive and are electrically connected to the n-type region of the photovoltaic diode, preferably either by being in contact with the n-type region or by being in contact with an electrically conductive intermediate layer which in turn is in contact with the n-type region or with another electrically conductive intermediate layer (i.e., any intermediate layers are electrically conductive).

The one or more intermediate layer, if present, can be used to reduce lattice mismatch and/or difference in thermal contraction between layers. Where a single intermediate layer is present, preferably the intermediate layer is also discontinuous (i.e., is in the form of a discontinuous layer including a plurality of separate intermediate elements), preferably arranged in a pattern which is similar to or identical to a pattern in which the photocathode elements are arranged. For example, preferably, for each photocathode element, the outlines of the photocathode element, in the width and depth directions, and the width and depth outlines of a corresponding intermediate element (1) differ only in their position in the thickness direction (e.g., the photocathode element and the intermediate element have abutting surfaces of substantially the same shape and surface area, and the photocathode element is above the intermediate element), (2) differ in their position in the thickness direction and the photocathode element width and depth outlines are all within the width and depth outlines of the intermediate element, or (3) differ in their position in the thickness direction and the intermediate element width and depth outlines are all within the width and depth outlines of the photocathode element. Where more than one intermediate layers are present, preferably each of them is also in the form of a discontinuous layer including a plurality of separate elements, likewise arranged in a pattern which is similar to or identical to a pattern in which the photocathode elements are arranged, or one (or more) of the intermediate layers (preferably all being closer to the photocathode than any continuous intermediate layer) is (or are each) likewise also in the form of a discontinuous layer including a plurality of separate elements, arranged in a pattern which is similar to or identical to a pattern in which the photocathode elements are arranged.

Any material which is suitable for use as a photocathode can be used to form the photocathode elements according to the present invention, a variety of which are known to those of skill in the art. The photocathode elements are preferably substantially transparent to at least most of the low energy (i.e., long wavelength) light, e.g., infrared light, in order to maximize the amount of light which reaches the underlying solar cell diode. Materials which absorb or reflect some of the low energy light, e.g., infrared light, could be used to form the photocathode elements, but would reduce the efficiency of the device, due to the absorbed or reflected light, unless an optical feature were provided which deflected or collected the light which would otherwise be absorbed or reflected by the photocathode elements and allowed some or all of that light to reach the diode.

For example, in the case of hydrolysis of water, several materials, each of which is suitable for use in making photocathode elements which are substantially transparent to low energy light, e.g., infrared light, are InGaP, GaP and GaN. Preferably, the photocathode elements have an appropriate hydrolysis catalyst (e.g., platinum, in the case of hydrolysis of water) deposited on one or more exposed surface (i.e., exposed to electrolyte solution during operation of the cell). Such catalyst material can be in any suitable shape, e.g., in the form of microspheres or monolayers.

Similarly, any material which is suitable for use as an intermediate layer (a variety of which are known to those of skill in the art) can be used to form intermediate elements, if present, according to the present invention. The intermediate elements are likewise preferably substantially transparent to at least most of the low energy light from the sun, e.g., infrared light, in order to maximize the amount of such light which reaches the diode. Materials which absorb or reflect some or all of the low energy light from the sun could be used to form the intermediate elements, but would reduce the efficiency of the device, due to the absorbed or reflected light, unless an optical feature were provided which deflected or collected the low energy light which would otherwise be absorbed or reflected by the intermediate elements and allowed some or all of that light to reach the diode.

The photocathode elements and any intermediate layer are preferably formed of respective crystalline materials having crystal structure (e.g., cubic, tetragonal, orthorhombic, monoclinic, triclinic, hexagonal, rhombohedral, etc.) which is similar to each other and to that of the substrate, although it is possible, in some instances, for layers which are in contact with each other to be of differing crystal structure without presenting lattice mismatch which is too extreme, in particular where one (or both) of the layers in contact is (or are each) in the form of a discontinuous layer including a plurality of elements.

The at least one anode element is electrically connected to the p-type region. Preferably, the at least one anode element is separate from the photovoltaic diode, and is electrically connected to the p-type region through a p-region contact layer provided on the p-type region and an anode line which provides electrical connection between the p-region contact layer and the anode. If desired or needed, a supplemental power source, e.g., a battery, can be provided, preferably along the anode line, to supplement the power being produced by the photovoltaic diode. However, generally, such a supplemental power source is not needed, i.e., the photovoltaic diode itself typically provides sufficient energy to run the photovoltaic-photoelectrochemical cell.

The p-region contact layer can be made of generally any electrically conductive material which is suitable for use as a p-region contact layer in conventional photovoltaic devices. A variety of materials are known to be suitable for use as a p-region contact layer. For example, suitable materials for use as a p-region contact layer include any conventional metallization material, as are commonly used, e.g., aluminum. As is well known, such a metallized layer can be formed by any suitable technique, e.g., by evaporation or plating, such techniques being well known.

The anode line can be made of generally any electrically conductive material, e.g., any suitable metal, such as copper wire, platinum wire, etc. Preferably, the conductive material is one which is resistant to corrosion.

The at least one anode element can generally be any structure which is suitable for use as an anode. In cases where water is being electrolyzed, a preferred anode element comprises platinum, in particular, platinum wire mesh.

As noted above, the photovoltaic-photoelectrochemical device preferably comprises at least one container comprising at least one bottom portion and at least one sidewall portion, so that when the photovoltaic-photoelectrochemical device is in use, the container can hold an electrolyte solution in which at least part of the photovoltaic device, in particular, the at least one anode and the photocathode elements, is immersed. The container can be made of any suitable material which can withstand the conditions to which it is subjected in the photovoltaic-photoelectrochemical process and the compounds with which it comes into contact.

As noted above, the container may further include a top portion. Preferably at least one region of the container is substantially transparent to at least most of the low energy light from the sun, e.g., infrared light, in particular where the container includes a top portion, so that at least the low energy light from the sun can enter through the container and be absorbed in either the n-region or the p-region of the diode. Most preferably, the entire container is substantially transparent to at least most of the low energy light. It is possible to direct sunlight through any desired portion of the container, e.g., by reflecting the sunlight so as to travel in a direction such that it passes through such desired portion of the container.

In addition, as noted above, the container preferably also has a photocathode reaction product vent and/or an anode reaction product vent. In addition, the photocathode reaction product vent may be connected (e.g., through a connecting pipe) to a tank for collection of the photocathode reaction product, and/or the anode reaction product vent may be connected (e.g., through a connecting pipe) to a tank for collection of the anode reaction product.

In use, an electrolyte solution is positioned in the container, the electrolyte solution comprising at least one electrolyzable compound, so that at least the photocathode elements and at least one anode of the photovoltaic-photoelectrochemical device are at least partially immersed in the electrolyte solution. In the case of electrolysis of water, the electrolyte solution comprises water and preferably also at least one acid, e.g., hydrochloric acid or sulfuric acid, so as to render the electrolyte solution slightly acidic.

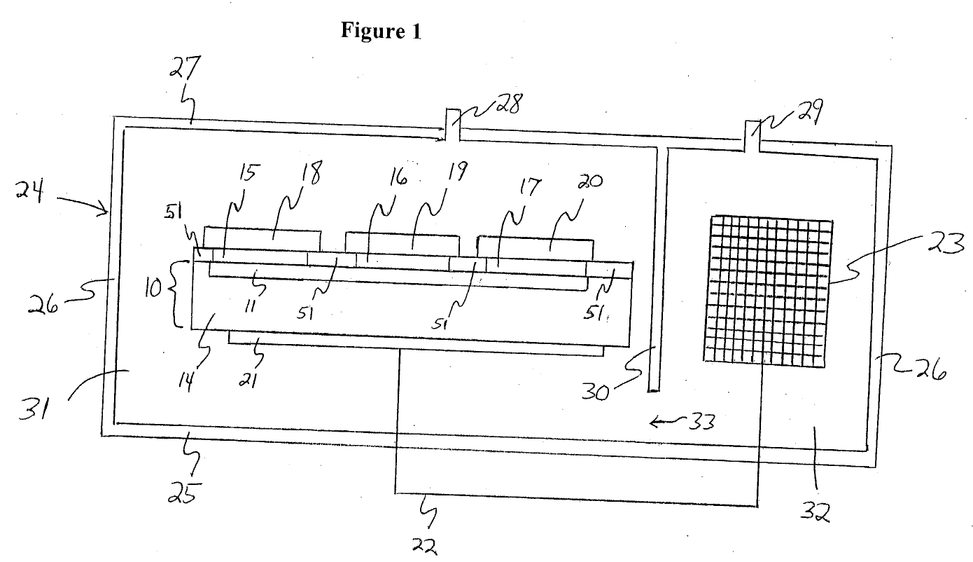

FIG. 1 depicts an exemplary embodiment of a photovoltaic-photoelectrochemical device in accordance with the present invention, the embodiment shown in FIG. 1 being a preferred embodiment. The photovoltaic-photoelectrochemical device depicted in FIG. 1 includes a solar cell diode 10 having an n-type region 11 and a p-type region 14. Three intermediate elements 15, 16 and 17 are positioned above the n-type region 11, respectively, and three photocathode elements 18, 19 and 20 are positioned above the intermediate elements 15, 16 and 17, respectively.

The n-type region 11 is formed of arsenic-doped polysilicon, and the p-type region 14 is formed of boron-doped polysilicon. The intermediate elements 15, 16 and 17 are each formed of gallium arsenide (GaAs), and the photocathode elements 18, 19 and 20 are each formed of indium gallium phosphide (InGaP). The photocathode elements 18, 19 and 20 each have platinum catalyst deposited on a top surface thereof. Above the diode 10 is a mask 51 of silica, formed in a manner as described below in the second embodiment of a method according to the present invention.

The preferred embodiment shown in FIG. 1 further includes a contact 21 formed on the bottom of the diode 10, in contact with the p-type region 14. The contact 21 is formed of aluminum, and is electrically connected to one end of an electrically conductive anode line 22, the other end of which is electrically connected to an anode element 23. The anode line 22 is formed of copper wire, and the anode element 23 is formed of platinum wire mesh.

The photovoltaic-photoelectrochemical device further comprises at least one container 24 comprising a bottom portion 25, sidewall portions 26 and a top portion 27. A photocathode reaction product vent 28 and an anode reaction product vent 29 are formed in the top portion 27.

In the preferred embodiment shown in FIG. 1, the photocathode reaction product vent 28 is positioned above the photocathode elements 18, 19 and 20, and the anode reaction product vent 29 is positioned above the anode element 23. The container 24 defines an internal volume which is gas-tight and liquid-tight, with the exception of the photocathode reaction product vent 28 and the anode reaction product vent 29.

The container 24 in the preferred embodiment depicted in FIG. 1 further comprises an internal partial wall 30 extending from the top portion 27 of the container 24 down toward, but not reaching, the bottom portion 25 of the container 24, the internal partial wall 30 dividing the internal volume within the container 24 into a first region 31 and a second region 32, but leaving a passageway 33 along the bottom of the container 24 for liquid communication between the first region 31 and the second region 32 (i.e., a passageway through which electrolyte can pass between the first region 31 and the second region 32). As depicted in FIG. 1, in the preferred embodiment, the diode 10, the intermediate elements 15, 16 and 17, the photocathode elements 18, 19 and 20 and the metal contact 21 are positioned within the first region 31, and the anode element 23 is positioned within the second region 32. Also, as depicted in FIG. 1, the first region 31 is adjacent to the photocathode reaction product vent 28, and the second region 32 is adjacent to the anode reaction product vent 29.

In the preferred embodiment depicted in FIG. 1, the anode line 22 passes from the metal contact 21, through the bottom portion 25 outside the container 24, back through the bottom portion 25 into the container 24 and to the anode element 23. The holes in the container 24 through which the anode line 22 passes are sealed in order to prevent leakage of any electrolyte solution.

In use, an electrolyte solution is filled in the container 24, preferably to a depth such that the photocathode elements 18, 19 and 20 and the anode element 23 are completely immersed in the electrolyte solution. The photovoltaic-photoelectrochemical device is placed in such a way that the diode 10 absorbs at least low energy light from the sun, such light preferably coming through the top portion 27 of the container 24, and into contact with the diode 10. As energy is produced by the diode 10, the net flow of electrons is from the anode element 23 to the photocathode elements 18, 19 and 20, driving the respective half-cell reactions and thereby producing photocathode reaction product at the photocathode elements 18, 19 and 20, and anode reaction product at the anode element 23. Where the electrolyte solution contains water as the electrolyzable compound, hydrogen is produced at the photocathode elements 18, 19 and 20, and bubbles up through the electrolyte solution and out the photocathode reaction product vent 28, and oxygen is produced at the anode element 23 and bubbles up through the electrolyte solution and out the anode reaction product vent 29.

As mentioned above, the diode in the photovoltaic-photoelectrochemical device according to the present invention can be any suitable type of diode, a variety of which are known. The n-type dopant and the p-type dopant can be introduced into the respective regions which will become the n-type region and the p-type region in any desired order. For example, a semiconductor substrate can be doped with p-type dopant to form one or more p-type region, followed by doping with an n-type dopant to form a plurality of n-type regions. If desired, however, the n-type doping could be carried out before the p-type doping, the n-type doping and the p-type doping could be carried out simultaneously, or the n-type doping and the p-type doping could be carried out alternatingly (e.g., some n-type doping, then some or all p-type doping, then more n-type doping, etc.). The n-doping and/or p-doping of the semiconductor substrate can be carried out before or after any of the intermediate elements and/or the photocathode elements are partially or completely formed. However, preferably, a semiconductor substrate is first doped with a p-type dopant to dope substantially the entirety of the substrate (before forming the intermediate elements, if any are to be formed, and the photocathode elements), and then specific regions of the p-doped substrate are doped with an n-type dopant to create n-type regions within the p-doped substrate (i.e., the regions other than the n-type regions comprise the p-type region) during or before the forming of the intermediate elements (if any are to be formed) and the photocathode elements. In a preferred aspect of the present invention, at least a portion of n-type doping of the semiconductor substrate occurs when depositing (at high temperatures) intermediate elements and/or photocathode elements directly on a p-type element or on one or more intermediate layers which have previously been formed on top of a p-type element (e.g., some of the phosphorus from depositing a layer of GaP or InGaP, or some of the arsenic from depositing a layer of GaAs can diffuse into a region of the silicon substrate (which may be undoped or which may be p-doped).

The photocathode elements and, when present, the intermediate elements, are formed using any epitaxial growth technique. A variety of epitaxial growth techniques are known. As is well known, epitaxial growth refers to any of a number of techniques where a second crystal structure is grown on a first crystal structure, using the first crystal structure as a seed (or model) for the growth of the second crystal structure. That is, the first crystal structure is seeding the growth of the second crystal structure, and the arrangement of the atoms of the second crystal which requires the lowest energy is a structure which substantially matches that of the first crystal. Thus, the second crystal structure is grown as a continuation of the crystal structure of the first crystal structure, with the atoms of the second crystal structure mimicking the orientation of the atoms in the first crystal structure, so that the second crystal structure has a high quality crystal structure (typically almost as high as the quality of the first crystal structure). The respective crystal structures each have a lattice constant, i.e., the distances between each atom in the crystal structure (in some structures, the distances between atoms is different depending on the location of the atom in the structure, and such structures therefore have a plurality of lattice constants). To the extent that the lattice constant of the second crystal differs from that of the first crystal, there is a degree of lattice mismatch. Crystal lattices can generally distort to some extent, so as to accommodate such mismatch without causing a lattice defect. However, if the dimensions of the interface between the first crystal and the second crystal are large enough, eventually the lattice mismatch will exceed the flexibility of the lattice (i.e., the ability of the lattice to distort), and a lattice defect will result. Lattice matching refers to selecting crystal structures whose lattice constants are sufficiently close to one another that one can be epitaxially grown on the other over a substantial surface area without causing lattice defects or unacceptably large lattice defect density. There are not many combinations of materials which can be lattice matched.

In addition, epitaxial growth is typically conducted at relatively high temperatures, and different crystal lattices typically expand and contract at different rates. Accordingly, upon cooling after epitaxial growth, such different contraction rates tend to cause additional stress in the respective layers.

According to the present invention, the effects of any lattice mismatch and/or any thermal contraction difference between the photocathode and the layer on which the photocathode is formed (and optionally between at least one intermediate layer, if any are present, and the respective layer on which it is formed) are minimized by forming the photocathode (and any such intermediate layer) as a discontinuous layer. As noted above, due to the unique nature of a photovoltaic-photoelectrochemical device, unlike other semiconductor devices and photovoltaic devices, the photocathode (and any intermediate layers) can be formed as a discontinuous layer, because electrical contact can readily be formed between an electrolyte solution and a discontinuous photocathode without the need to provide any structure which electrically links the separate photocathode elements together.

The photocathode elements (and optionally the intermediate layers) can be deposited discontinuously (e.g., by selective epitaxy, i.e., where the deposition of the photocathode material onto a surface of a structure which has at least two materials is conducted under conditions where the photocathode material will deposit on one or more of the materials but not on the other material[s]), or can be deposited and then patterned, e.g., by photolithography.

Chemical vapor deposition is one group of epitaxial growth techniques. In the term “chemical vapor deposition”, the word “vapor” indicates that a gas is used, and the word “chemical” indicates that a chemical reaction occurs, in carrying out the deposition. Chemical vapor deposition techniques often use a vacuum. In an example of a chemical vapor deposition technique, a substrate is provided, e.g., in a tube or a bell jar, and the substrate is heated to a deposition temperature. A gas containing the compound to be deposited on the substrate is passed across the heated substrate (e.g., by passing it through the tube). For example, where germanium is being deposited on a substrate, GeH₄ gas can be passed across a heated substrate (for this particular process, about 800 degrees C. is a suitable temperature), and as the GeH₄ gas passes over the substrate, the GeH₄ gas, which is unstable at high temperatures, decomposes into solid germanium, which deposits on the substrate, and hydrogen gas, which continues flowing in the direction of the gas flow across the substrate.

Physical vapor deposition is another group of epitaxial growth techniques. Physical vapor deposition techniques almost always require a high vacuum. In an example of a physical vapor deposition technique, a material in solid form (e.g., germanium) is heated to a temperature at which it vaporizes, and a substrate is positioned near the solid material, so that as the material vaporizes, it deposits onto the substrate.

Close-spaced vapor transport is a type of epitaxial technique which includes aspects of both chemical vapor deposition and physical vapor deposition. Close-spaced vapor transport can generally be conducted at atmospheric pressure. In a close-spaced vapor transport technique, a transport agent is passed through a small gap (e.g., having a height of about 1 mm) between a solid piece of a material to be deposited and a substrate. The solid is heated to a temperature at which it vaporizes (in the case of germanium, about 850 degrees C. is a suitable temperature). The transport agent includes a gaseous compound which reacts with the vaporized material to be deposited to form a deposition compound. In the case of a process for depositing germanium, hydrochloric acid is an example of a suitable transport agent, and it reacts with germanium to form germanium chloride (the deposition compound), releasing a hydrogen ion. The substrate is heated to a temperature at which the deposition compound plates out (in the case of germanium chloride, a suitable temperature is about 600 degrees C.), releasing the part of the deposition compound which came from the transport agent, and is recycled, along with the other original component of the transport agent (i.e., where the transport agent is hydrochloric acid, the chloride ion is released from the deposition compound and is recycled along with the hydrogen ion which was released when the transport agent reacted with the vaporized material.

Liquid phase epitaxy is a very simple epitaxial process, in one form involving merely dipping a solid material including a crystalline substrate into a liquid solution containing the material to be deposited. Typically the substrate is at a temperature which is lower than the solution, so that upon contact with the substrate, the solution in the region of the substrate cools somewhat (e.g., about 10 degrees C.) and precipitates onto the substrate. Such processes are extremely selective, i.e., they require very low lattice mismatch. That is, unless the crystalline substrate and the material to be deposited have very low lattice mismatch, the material will not deposit on the substrate.

Close-spaced vapor transport can be a selective epitaxial process, i.e., it can be conducted under conditions whereby the material being deposited grows on one or more materials (i.e., where there is a very low degree of lattice mismatch) but not on another material or materials (where there is a higher degree of lattice mismatch). Likewise, chemical vapor deposition (in some cases) and liquid phase epitaxy (in almost all cases) can be conducted as selective epitaxial processes. Physical vapor deposition generally does not provide selective epitaxy.

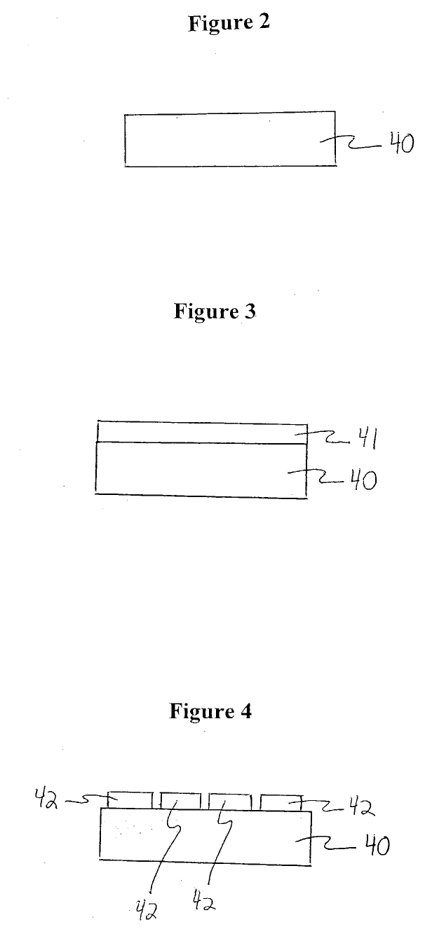

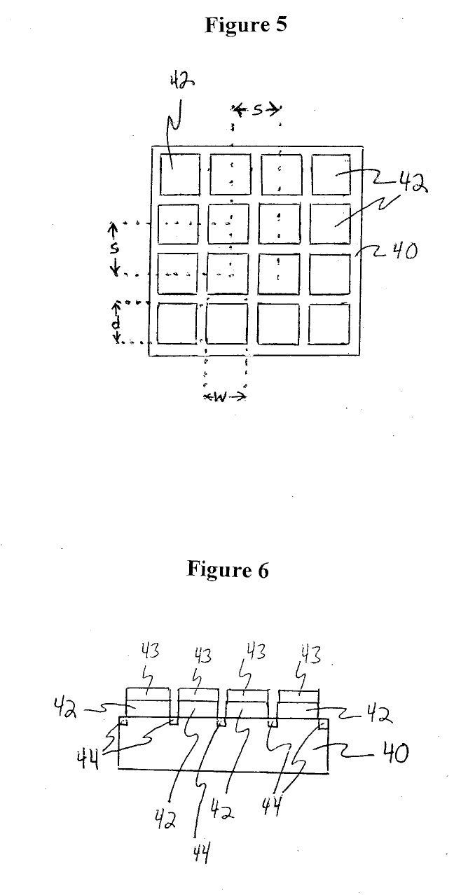

In a first preferred embodiment of a process according to the present invention for forming intermediate elements and photocathode elements on a polycrystalline silicon substrate 40 (see FIG. 2), a GaAs film 41 is applied to a surface of the substrate (see FIG. 3) by close-spaced vapor transport. The GaAs film 41 is then patterned (by any suitable patterning technique, a variety of which are known to those skilled in the art, e.g., photolithography and etching) into a plurality of GaAs intermediate elements 42 (see FIG. 4). FIG. 5 is an overhead view of the intermediate elements 42 on the substrate (FIG. 4 being a side view) showing the pattern of the GaAs intermediate elements 42, each separated from each other by gaps.

In this embodiment, the GaAs mesas each have a thickness (in the vertical direction in FIG. 4) of about 0.2 micrometer (a range of thicknesses up to 5 microns or more is possible), width w and depth d (see FIG. 5) of about 35 micrometers, and spacing on center s (see FIG. 5) of about 50 micrometers. The size of the mesas is not restricted, although the mesas are preferably of a size which is small enough to achieve a significant benefit by way of the present invention, e.g., the mesas having width and depth which are each not larger than 1 mm. That is, suitable widths and depths for the mesas might include sub-micron (e.g., as small as they can be formed), 10 micrometers, 20 micrometers, 30 micrometers, 40 micrometers, 50 micrometers, 60 micrometers, 70 micrometers, 80 micrometers, 90 micrometers, 100 micrometers, 200 micrometers, 300 micrometers, 400 micrometers, 500 micrometers, 600 micrometers, 700 micrometers, 800 micrometers, 900 micrometers, etc., and suitable spacing on center might include such distances plus gaps in the range of sub-micron, 1 micrometer, 2 micrometer, 3 micrometer, 4 micrometer, 5 micrometer, 6 micrometer, 7 micrometer, 8 micrometer, 9 micrometer, 10 micrometers, 20 micrometers, 30 micrometers, 40 micrometers, 50 micrometers, 60 micrometers, 70 micrometers, 80 micrometers, 90 micrometers, 100 micrometers, 200 micrometers, etc. Preferably, the gaps are as small as possible.

Next, photocathode elements 43 of In_{0.5}Ga_{0.5}P are deposited by liquid phase epitaxy. As shown in FIG. 6, one such photocathode element 43 is formed on each intermediate element 42. In the formation of the photocathode elements, the liquid phase epitaxy is selective (i.e., InGaP photocathode elements are formed only on the intermediate elements 42 and not elsewhere) by virtue of the preferential nucleation of InGaP on the GaAs mesas rather than directly on the exposed silicon. Nucleation of InGaP directly on silicon by liquid phase epitaxy is unfavorable due to the lattice mismatch. Incidentally, due to the high temperature of the liquid phase epitaxy step, the exposed silicon is converted to regions of silica 44. Other methods of epitaxial growth are also workable.

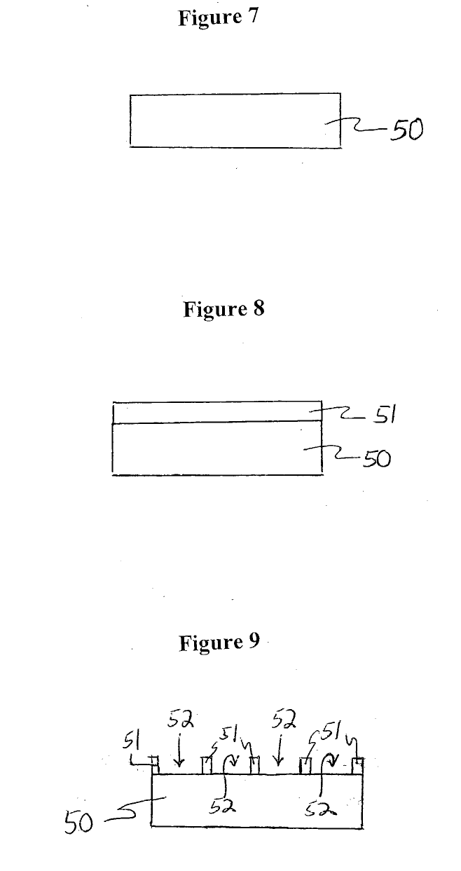

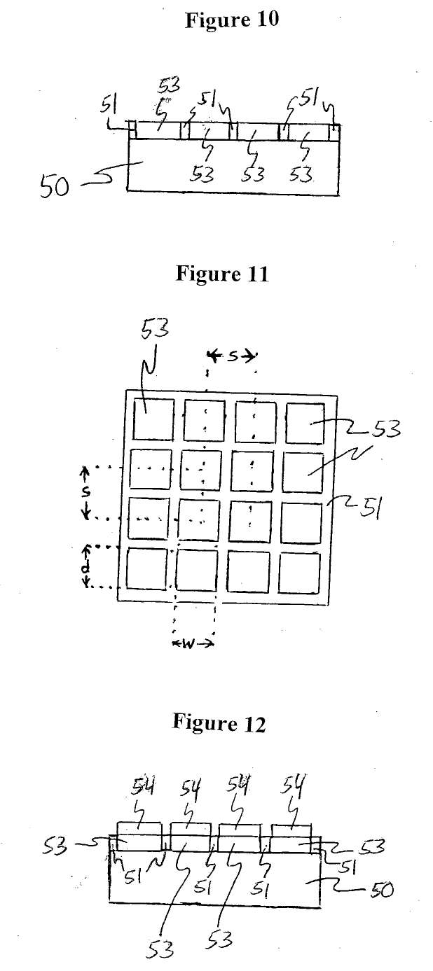

In a second preferred embodiment of a process according to the present invention for forming intermediate elements and photocathode elements on a polysilicon substrate, there is provided a polysilicon substrate 50 (see FIG. 7). The substrate 50 is then heated to produce a thermally-grown silicon dioxide layer 51 (see FIG. 8) having a thickness of from about 150 mm to about 200 mm. Using photolithography and selective etching (e.g., with buffered HF), the thermally-grown silicon dioxide layer is patterned to form an oxide mask 51 with openings 52 (see FIG. 9) which expose the underlying silicon. The openings 52 serve as sites for preferential nucleation of regions of GaAs 53 (see FIG. 10) in a close-spaced vapor transport step. FIG. 11 is an overhead view of the intermediate elements 53 and the oxide mask 51 on the substrate (FIG. 10 being a side view) showing the pattern of the GaAs intermediate elements 53. In this embodiment also, the GaAs intermediate elements each have a thickness (in the vertical direction in FIG. 10) of about 0.2 micrometer, width w and depth d (see FIG. 11) of about 35 micrometers, and spacing on center s (see FIG. 11) of about 50 micrometers. Next, photocathode elements 54 of In_{0.5}Ga_{0.5}P are deposited by liquid phase epitaxy. As shown in FIG. 12, one such photocathode element 54 is formed on each intermediate element 53. In the formation of the photocathode elements, the liquid phase epitaxy is selective.

Preferably, in either the first or the second above-described embodiments of processes according to the present invention for forming intermediate elements and photocathode elements on a polycrystalline silicon substrate, the GaAs close-spaced vapor transport process is based on a reversible transport reaction that uses water vapor as a transport agent:

$$2 GaAs ( s ) + {H}_{2} O ( v ) {{⇌}^{T2}}_{T1} {Ga}_{2} O ( v ) + {H}_{2} ( g ) + {As}_{2} ( v ) \{ or 1 / 2 {As}_{4} ( v ) \}$$

A GaAs source and the silicon seed are separated by a distance of about 1 mm. The source (at a temperature T₂, preferably about 850 degrees C.) and seed (at a temperature T₁, preferably about 800 degrees C.) are heated individually in an infrared light-based fused silica tube furnace.

Preferably, in these embodiments, the InGaP liquid phase epitaxy is carried out using a standard horizontal slideboat technique as is commonly employed for research in and production of various compound semiconductor optoelectronics devices such as light-emitting diodes, semiconductor lasers, detectors, and solar cells. The atomic fractions of indium, gallium and phosphorus are preferably about X₁ₙ=0.962, X_{Ga}=0.011 and X_{P}=0.027. The melts are comprised of, e.g., 5 g indium, 51 mg GaP and 107 mg InP. In what is essentially a step cooling technique, the substrate is preferably contacted with supersaturated melt at a temperature in the range of from about 760 degrees C. to about 790 degrees C., preferably at a temperature of about 781 degrees C.

Without using selective epitaxy of the present invention (i.e., without forming each of the GaAs layer and the InGaP layer as a plurality of separate elements according to the present invention), InGaP/GaAs-on-silicon films are highly prone to cracking and peeling, and have an extremely rough surface morphology.

A useful feature of the GaAs-on-silicon close-spaced vapor transport process described above is that some arsenic diffuses into a p-type silicon substrate to form the n-type region (emitter) of the silicon solar cell, which can serve to forward bias the InGaP electrolysis cell.

In a third embodiment of a process according to the present invention for forming intermediate elements and photocathode elements on a polycrystalline silicon substrate, a GaAs film is applied to a surface of the substrate by close-spaced vapor transport, as in the first preferred process embodiment, but the GaAs film is not patterned before depositing the layer of In_{0.5}Ga_{0.5}P, which is, as in the first preferred process embodiment, deposited by liquid phase epitaxy. After depositing the layer of In_{0.5}Ga_{0.5}P, the layer of In_{0.5}Ga_{0.5}P and preferably also the GaAs film are then patterned, e.g., by photolithography, to form the photocathode elements and preferably also the intermediate elements. Optionally, after patterning, the photocathode elements (and preferably also the intermediate elements) are heated to a high temperature to anneal out some or all defects, if any.

In a fourth embodiment of a process according to the present invention, a photocathode layer, e.g., of InGaP, is formed directly on a polycrystalline silicon substrate (in the case of InGaP, by a process other than liquid phase epitaxy, e.g., by chemical vapor deposition or by close-spaced vapor transport), and the photocathode layer is then patterned, e.g., by photolithography to form a plurality of photocathode elements. Optionally, after patterning, the photocathode elements are heated to a high temperature to anneal out some or all defects, if any.

In a fifth embodiment of a process according to the present invention, one or more intermediate layers, and then a photocathode layer, are formed on a solar cell diode. The photocathode layer (and optionally one or more of the intermediate layers) is then patterned, e.g., by photolithography to form a plurality of photocathode elements (and optionally a plurality of intermediate elements). Optionally, after patterning, the photocathode elements and the intermediate elements are heated to a high temperature to anneal out some or all defects, if any.

Any two or more structural parts of the photovoltaic-photoelectrochemical devices can be integrated; any structural part of the photovoltaic-photoelectrochemical devices can be provided in two or more parts (which are held together, if necessary), etc.

1. A photovoltaic-photoelectrochemical device, comprising:
at least one container comprising at least one bottom portion and at least one sidewall portion;
an electrolyte solution positioned in said at least one container, said electrolyte solution comprising at least one electrolyzable compound;
at least one diode comprising at least one n-type region and at least one p-type region, said at least one n-type region and said at least one p-type region being in contact with each other, thereby forming at least one p-n junction; and
a plurality of separate photocathode elements positioned within said at least one container, each said photocathode element being electrically connected with said at least one n-type region, each said photocathode element comprising electrically conductive material, each said photocathode element being at least partially immersed in said electrolyte solution.

2. A photovoltaic-photoelectrochemical device as recited in claim 1, wherein said at least one electrolyzable compound comprises H₂O.

3. A photovoltaic-photoelectrochemical device as recited in claim 1, wherein said at least one diode comprises silicon having at least a first portion thereof doped with at least one n-type dopant to form said at least one n-type region, and at least a second portion thereof doped with at least one p-type dopant to form said at least one p-type region.

4. A photovoltaic-photoelectrochemical device as recited in claim 1, wherein said at least one diode comprises a doped polycrystalline material.

5. A photovoltaic-photoelectrochemical device as recited in claim 1, wherein each of said photocathode elements are substantially transparent to at least infrared light.

6. A photovoltaic-photoelectrochemical device as recited in claim 1, wherein two or more of said photocathode elements each comprise at least one material selected from the group consisting of InGaP, GaP, GaN and InGaN.

7. A photovoltaic-photoelectrochemical device as recited in claim 1, wherein said electrolyte solution comprises at least one acidic compound.

8. A photovoltaic-photoelectrochemical device as recited in claim 1, further comprising at least one anode element which is electrically connected to said at least one p-type region.

9. A photovoltaic-photoelectrochemical device as recited in claim 8, wherein said at least one container further comprises at least one top portion, and at least one photocathode reaction product vent and said at least one anode reaction product vent are formed in said at least one top portion.

10. A photovoltaic-photoelectrochemical device as recited in claim 8, wherein said at least one container further comprises at least one top portion, and said at least one container further comprises at least one internal partial wall extending from said at least one top portion toward, but not reaching, said at least one bottom portion, said at least one internal partial wall being positioned between said plurality of separate photocathode elements and said at least one anode element.

11. A photovoltaic-photoelectrochemical device as recited in claim 1, further comprising at least one metal material or semiconductor material formed on said photocathode elements.

12. A photovoltaic-photoelectrochemical device as recited in claim 11, wherein said metal material comprises platinum.

13. A photovoltaic-photoelectrochemical device, comprising:
at least one container comprising at least one bottom portion, at least one sidewall portion and at least one top portion, at least one photocathode reaction product vent and at least one anode reaction product vent being formed in said at least one container, said at least one container defining an internal volume which is substantially gas-tight, with the exception of said at least one photocathode reaction product vent and said at least one anode reaction product vent;
at least one diode comprising at least one n-type region and at least one p-type region, said at least one n-type region and said at least one p-type region being in contact with each other, so as to form at least one p-n junction; and
a plurality of separate photocathode elements positioned within said at least one container, each said photocathode element being electrically connected with said at least one n-type region, each said photocathode element comprising electrically conductive material.

14. A photovoltaic-photoelectrochemical device as recited in claim 13, wherein said device further comprises at least one anode element, and said at least one container further comprises at least one internal partial wall extending from said at least one top portion toward, but not reaching, said at least one bottom portion, said at least one internal partial wall being positioned between said plurality of separate photocathode elements and said at least one anode element.

15. A photovoltaic-photoelectrochemical device, comprising:
at least one container comprising at least one bottom portion, at least one sidewall portion and at least one top portion;
at least one diode comprising at least one n-type region and at least one p-type region, said at least one n-type region and said at least one p-type region being in contact with each other, so as to form at least one p-n junction;
a plurality of separate photocathode elements positioned within said at least one container, each said photocathode element being electrically connected with said at least one n-type region, each said photocathode element comprising electrically conductive material; and
at least one anode element which is electrically connected to said at least one p-type region,
said at least one container further comprising at least one internal partial wall extending from said at least one top portion toward, but not reaching, said at least one bottom portion, said at least one internal partial wall being positioned between said plurality of separate photocathode elements and said at least one anode element.

16. A photovoltaic-photoelectrochemical device, comprising:
at least one diode, said at least one diode comprising a doped polycrystalline material and having at least one n-type region and at least one p-type region, said at least one n-type region and said at least one p-type region being in contact with each other, so as to form a p-n junction; and
a plurality of separate photocathode elements, each said photocathode element being electrically connected with said at least one n-type region, each said photocathode element comprising electrically conductive material.

17. A photovoltaic-photoelectrochemical device as recited in claim 16, wherein said polycrystalline material is polysilicon.

18. A photovoltaic-photoelectrochemical process, comprising:
subjecting to light at least one diode, said at least one diode comprising at least one n-type region and at least one p-type region, said at least one n-type region and said at least one p-type region being in contact with each other, thereby forming at least one p-n junction, said at least one n-type region being electrically connected with a plurality of separate photocathode elements, each said photocathode element comprising electrically conductive material, said plurality of photocathode elements being positioned in at least one container, said at least one container comprising at least one bottom portion and at least one sidewall portion, an electrolyte solution being positioned in said container, said electrolyte solution comprising at least one electrolyzable compound, each said photocathode element being at least partially immersed in said electrolyte solution.

19. A method of making a photovoltaic-photoelectrochemical device, comprising:
doping at least a first region of a semiconductor substrate with at least one p-dopant to form at least one p-type region of a diode;
doping at least a second region of said semiconductor substrate with at least one n-dopant to form at least one n-type region of said diode, said at least one n-type region and said at least one p-type region being in contact with each other, thereby forming at least one p-n junction;
epitaxially forming a plurality of separate photocathode elements on said diode, each said photocathode element comprising electrically conductive material and being electrically connected with said at least one n-type region; and
at least partially immersing said photocathode elements in an electrolyte solution positioned in a container, said container comprising at least one bottom portion and at least one sidewall portion, said electrolyte solution comprising at least one electrolyzable compound.

20. A method as recited in claim 19, wherein said doping at least a first region is conducted before said doping at least a second region.

21. A method as recited in claim 19, wherein said doping at least a second region results from said epitaxially forming a plurality of separate photocathode elements.

22. A method as recited in claim 19, wherein a portion of said doping at least a second region results from said epitaxially forming a plurality of separate photocathode elements.

23. A method as recited in claim 19, further comprising epitaxially forming at least one intermediate layer on said at least one n-type region prior to said epitaxially forming a plurality of separate photocathode elements, whereby said at least one intermediate layer is positioned between said at least one n-type region and said photocathode elements.

24. A method as recited in claim 23, wherein said doping at least a second region results from said epitaxially forming said at least one intermediate layer.

25. A method as recited in claim 23, wherein a portion of said doping at least a second region results from said epitaxially forming said at least one intermediate layer.

26. A method as recited in claim 19, wherein said epitaxially forming a plurality of separate photocathode elements is performed by chemical vapor deposition.

27. A method as recited in claim 23, wherein said epitaxially forming at least one intermediate layer is performed by close-spaced vapor transport.

28. A method as recited in claim 23, wherein said epitaxially forming a plurality of separate photocathode elements is performed by liquid phase epitaxy.

29. A method of making a photovoltaic-photoelectrochemical device, comprising:
doping at least a first region of a polycrystalline semiconductor substrate with at least one p-dopant to form at least one p-type region of a diode;
doping at least a second region of said polycrystalline semiconductor substrate with at least one n-dopant to form at least one n-type region of said diode, said at least one n-type region and said at least one p-type region being in contact with each other, thereby forming at least one p-n junction; and
epitaxially forming a plurality of separate photocathode elements on said diode, each said photocathode element comprising electrically conductive material and being electrically connected with said at least one n-type region.

30. A method of making a photovoltaic-photoelectrochemical device, comprising:
doping at least a first region of a semiconductor substrate with at least one p-dopant to form at least one p-type region of a diode;
doping at least a second region of said semiconductor substrate with at least one n-dopant to form at least one n-type region of said diode, said at least one n-type region and said at least one p-type region being in contact with each other, thereby forming at least one p-n junction;
epitaxially forming a plurality of separate photocathode elements on said diode, each said photocathode element comprising electrically conductive material and being electrically connected with said at least one n-type region; and
positioning said diode and said photocathode elements in a container comprising at least one bottom portion, at least one sidewall portion and at least one top portion, at least one photocathode reaction product vent and at least one anode reaction product vent being formed in said container, said container defining an internal volume which is substantially gas-tight, with the exception of said at least one photocathode reaction product vent and said at least one anode reaction product vent.

31. A method of making a photovoltaic-photoelectrochemical device, comprising:
doping at least a first region of a semiconductor substrate with at least one p-dopant to form at least one p-type region of a diode;
doping at least a second region of said semiconductor substrate with at least one n-dopant to form at least one n-type region of said diode, said at least one n-type region and said at least one p-type region being in contact with each other, thereby forming at least one p-n junction;
epitaxially forming a plurality of separate photocathode elements on said diode, each said photocathode element comprising electrically conductive material and being electrically connected with said at least one n-type region;
electrically connecting said at least one p-type region to at least one anode element; and
positioning said diode, said photocathode elements and said at least one anode element in a container, said container comprising at least one bottom portion, at least one sidewall portion, at least one top portion, and at least one internal partial wall extending from said at least one top portion toward, but not reaching, said at least one bottom portion, such that said at least one internal partial wall is positioned between said plurality of separate photocathode elements and said at least one anode element.
